(19) United States
(12) Patent Application Publication
(10) Pub. No.: US 2015/0187956 A1
(43) Pub. Date: Jul. 2, 2015

(54) IGZO Devices with Increased Drive Current and Methods for Forming the Same

(71) Applicant: Intermolecular Inc., San Jose, CA (US)

(72) Inventor: Khaled Ahmed, Anaheim, CA (US)

(73) Assignee: Intermolecular Inc., San Jose, CA (US)

(21) Appl. No.: 14/140,777

(22) Filed: Dec. 26, 2013

(51) Int. Cl. H01L 29/786; H01L 29/66

(52) U.S. Cl. CPC H01L 29/78609; H01L 29/66969; H01L 29/7869

(57) ABSTRACT

Embodiments described herein provide indium-gallium-zinc oxide (IGZO) devices, such as IGZO thin-film transistors (TFTs), and methods for forming such devices. A substrate is provided. A gate electrode is formed above the substrate. A gate dielectric layer is formed above the gate electrode. The gate dielectric layer includes titanium. An interface layer is formed above the gate dielectric layer. The interface layer includes silicon. An IGZO channel layer is formed above the interface layer. A source electrode and a drain electrode are formed above the IGZO channel layer.

### TECHNICAL FIELD

The present invention relates to indium-gallium-zinc oxide (IGZO) devices. More particularly, this invention relates to methods for forming IGZO devices, such as thin-film transistors (TFTs), with increased drive current and methods for forming such devices.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications. IGZO devices typically utilize amorphous IGZO (a-IGZO).

Recent developments in the field suggest that the use of crystalline IGZO may provide improved electrical and chemical stability in certain conditions. However, IGZO TFTs may lack electrical stability under negative bias illumination temperature stress (NBITS). A complete understanding of why this instability occurs in oxide semiconductors is crucial to prevent it from happening, and there have been many attempts to explain its origin, the major two arguments being the charge trapping model and the ion diffusion model. Recent reports support the charge trapping model, where holes generated in the IGZO layer upon illumination tunnel into traps in the gate dielectric when the gate electrode is negatively biased and cause a negative threshold shift.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with an interface layer formed above the gate dielectric layer.

FIG. 4 is a cross-sectional view of the substrate of FIG. 3 with an indium-gallium-zinc oxide (IGZO) layer formed above the interface layer.

FIG. 5 is a cross-sectional view of the substrate of FIG. 4 with an IGZO channel layer formed above the interface layer.

FIG. 6 is a cross-sectional view of the substrate of FIG. 5 with source and drain electrodes formed above the IGZO channel layer.

FIG. 7 is a cross-sectional view of the substrate of FIG. 6 with a passivation layer formed above the source and drain electrodes.

FIGS. 8 and 9 are diagrams comparing the energy bands of various materials.

FIG. 10 is a simplified cross-sectional diagram of a plasma enhanced chemical vapor deposition (PECVD) tool according to some embodiments.

FIG. 11 is a simplified cross-sectional diagram of a physical vapor deposition (PVD) tool according to some embodiments.

FIG. 12 is a flow chart illustrating a method for forming IGZO devices according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide indium-gallium-zinc oxide (IGZO) devices, such as IGZO thin-film transistors (TFTs), with reduced threshold voltage shift, such as when under negative bias illumination temperature stress (NBITS). In some embodiments, to address this problem, the “hole barrier height” at the interface of the gate dielectric and the IGZO channel layer is increased, while also achieving a high gate capacitance along with reduced gate leakage current.

In some embodiments, this is accomplished by utilizing a titanium oxide gate dielectric layer and forming a layer of silicon oxide above the gate dielectric layer before the IGZO channel layer is formed. The silicon oxide layer may have a thickness of, for example, between about 5 nanometers (nm) and about 20 nm. The titanium oxide gate dielectric layer may have a thickness of, for example, between about 150 nm and about 200 nm. In some embodiments, the silicon oxide layer is formed using plasma-enhanced chemical vapor deposition (PECVD), and the titanium oxide gate dielectric layer is formed using physical vapor deposition (PVD), chemical vapor deposition (CVD), PECVD, or atomic layer deposition (ALD).

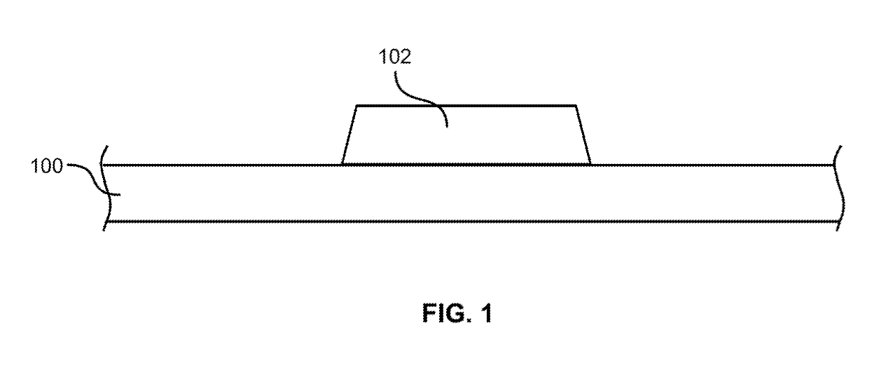

FIGS. 1-7 illustrate a method for forming an IGZO TFT (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between about 0.01 centimeters (cm) and about 0.5 cm. Although only a portion of the substrate 100 is shown, it should be understood that the substrate 100 may have a width of, for example, between about 5.0 cm and about 4.0 meters (m). Although not shown, in some embodiments, the substrate 102 may have a dielectric layer (e.g., silicon oxide) formed above an upper surface thereof. In such embodiments, the components described below are formed above the dielectric layer. Also, in some embodiments, the substrate 100 is at least partially made of a of a semiconductor material (e.g., silicon, germanium, gallium arsenide, etc.). For example, in some embodiments, the substrate includes glass with a layer of semiconductor material formed thereon.

Still referring to FIG. 1, a gate electrode 102 is formed above the substrate 100. In some embodiments, the gate electrode 102 is made of a conductive material, such as copper, silver, aluminum, manganese, molybdenum, or a combination thereof. The gate electrode may have a thickness of, for example, between about 20 nm and about 500 nm. Although not shown, it should be understood that in some embodiments, a seed layer (e.g., a copper alloy) is formed between the substrate 100 and the gate electrode 102.

It should be understood that the various components above the substrate, such as the gate electrode 102 and those described below, are formed using processing techniques suitable for the particular materials being deposited, such as PVD (e.g., co-sputtering in some embodiments), CVD, PECVD, electroplating, etc. Furthermore, although not specifically shown in the figures, it should be understood that the various components formed above the substrate 100, such as the gate electrode 102, may be sized and shaped using a photolithography process and an etching process, as is commonly understood, such that the components are formed above selected regions of the substrate 100.

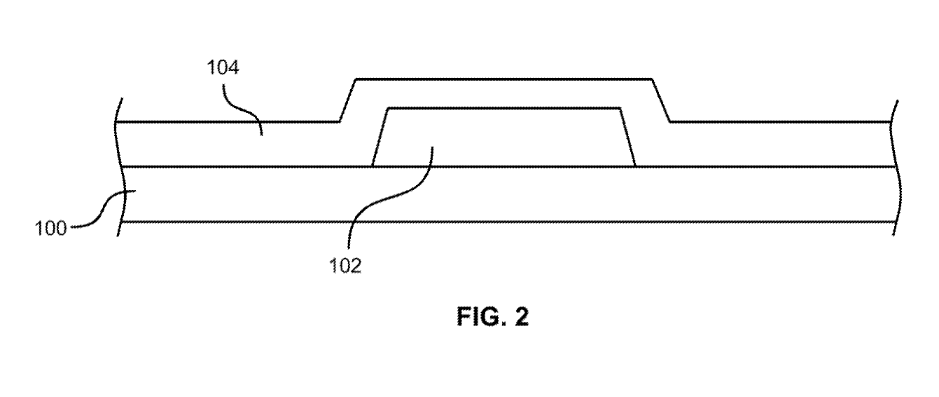

Referring to FIG. 2, a gate dielectric layer 104 is then formed above the gate electrode 102 and the exposed portions of the substrate 100. In some embodiments, the gate dielectric layer 104 includes titanium. The gate dielectric layer 104 may be made of, for example, titanium oxide. In some embodiments, the gate dielectric layer 104 has a thickness of, for example, between about 150 nm and about 200 nm. The gate dielectric layer may be formed using, for example, PVD, CVD, PECVD, or ALD.

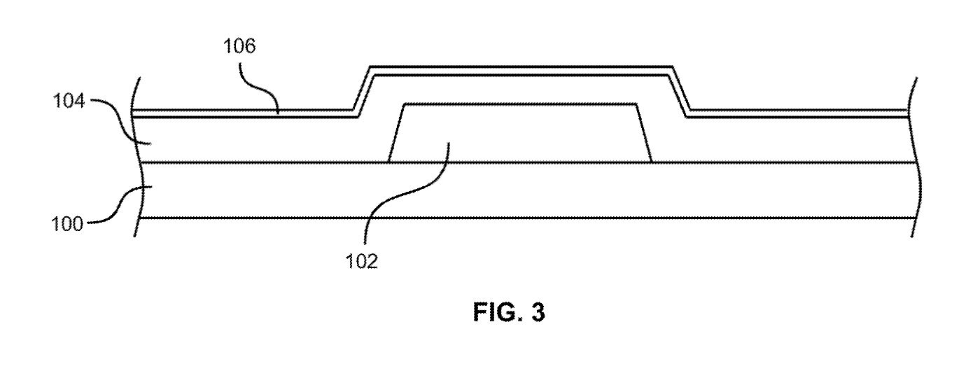

As shown in FIG. 3, an interface (or barrier) layer (or gate interface layer) 106 is formed above the gate dielectric layer 104. In some embodiments, the interface layer 106 includes silicon. The interface layer may include (or be made of) silicon oxide. The interface layer may have a thickness of, for example, between about 5 nm and about 20 nm. In some embodiments, the interface layer 106 is formed using PECVD.

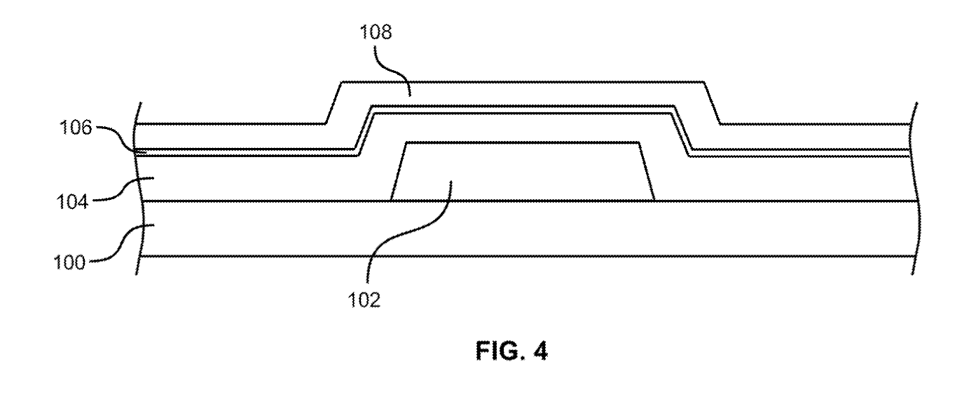

Referring now to FIG. 4, an IGZO layer 108 is then formed above the interface layer 106. The IGZO layer 108 may be made of IGZO in which a ratio of the respective elements is, for example, 1:1:1:1-3. In some embodiments, the IGZO within the IGZO layer 108 is deposited as amorphous IGZO (a-IGZO). However, in some embodiments, the IGZO is formed or deposited using processing conditions to enhance the crystalline structure thereof. In some embodiments, the IGZO layer 108 is formed using PVD. The IGZO may be deposited from a single target that includes indium, gallium, and zinc (e.g., an indium-gallium-zinc alloy target or an IGZO target), but two or more targets may also used (e.g., co-sputtering with an indium-zinc target and a gallium target). The IGZO layer 108 may have a thickness of, for example, between about 30 nm and about 100 nm, such as about 50 nm. It should be noted that in at least some embodiments, the IGZO layer 108 (and the IGZO channel layer described below), the interface layer 106, and the gate dielectric layer 104 are all made of different materials (e.g., the interface layer 106 is made of a different material than the gate dielectric layer 104 and the IGZO layer 108).

Although not specifically shown, in some embodiments, the IGZO layer 108 (and the other components shown in FIG. 4) may then undergo an annealing process. In some embodiments, the annealing process includes a relatively low temperature (e.g., less than about 600° C., preferably less than about 450° C.) heating process in, for example, an ambient gaseous environment (e.g., nitrogen, oxygen, or ambient/air) to (further) enhance the crystalline structure of the IGZO. The heating process may occur for between about 1 minute and about 200 minutes. After the annealing (or heating) process, the IGZO layer 108 may (substantially) include crystalline IGZO (c-IGZO). As used herein a “crystalline” material (e.g., c-IGZO) may be considered to be one that is more than 30% crystalline by volume, as determined by a technique such as X-ray Diffraction (XRD). In some embodiments, the c-IGZO is c-axis aligned crystal (CAAC) IGZO, as is commonly understood.

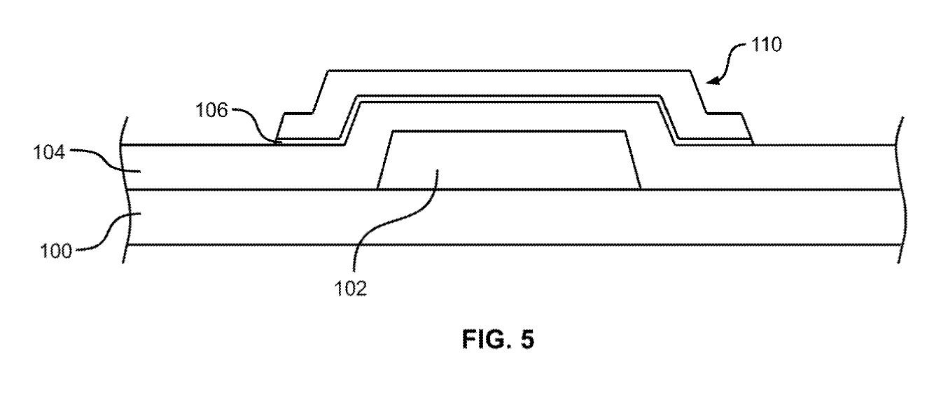

Referring to FIG. 5, after the annealing process, the IGZO layer 108 is patterned (e.g., etched) to form an IGZO channel (or channel layer) 110 (e.g., made of substantially c-IGZO) above the interface layer 106, over the gate electrode 102. In the depicted embodiment, the interface layer 106 has also been patterned/etched (e.g., using the same, or a different, etching process used to define the IGZO channel layer 110) such that the only remaining portions of the interface layer 106 are directly between the gate dielectric layer 104 and the IGZO channel layer 110. In such embodiments, the interface layer 106 may be considered to be a portion of the IGZO channel layer 110 (i.e., a composite or bi-layer IGZO channel layer). However, in some embodiments, the interface layer 106 is not patterned and is left as shown in FIGS. 3 and 4.

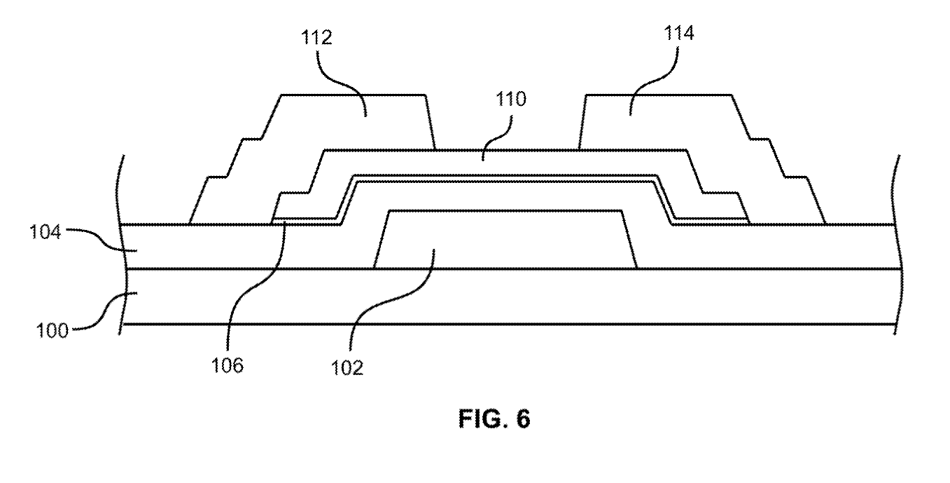

Referring now to FIG. 6, a source electrode (or region) 112 and a drain electrode (or region) 114 are then formed above the IGZO channel layer 110. As shown, the source electrode 112 and the drain electrode 114 lie on opposing sides of, and partially overlap the ends of, the IGZO channel layer 110 (and the interface layer 106 in the depicted embodiment). As will be appreciated by one skilled in the art, the source electrode 112 and the drain electrode 114 may be defined as shown in FIG. 6 using a “back-channel etch” (BCE) process to, for example, form the gap between the source electrode 112 and the drain electrode 114, which is vertically aligned with the gate electrode 102. However, in some embodiments, an etch-stop layer, as is commonly understood, may be formed above the IGZO channel layer 110 to facilitate the defining of the source electrode 112 and the drain electrode 114 (e.g., by protecting the IGZO during the etch process).

In some embodiments, the source electrode 112 and the drain electrode 114 are made of titanium, aluminum, molybdenum, copper, copper-manganese alloy, or a combination thereof. In some embodiments, the source electrode 112 and the drain electrode 114 include multiple sub-layers (e.g., sub-layers of titanium and titanium nitride). The source electrode 112 and the drain electrode 114 may have a thickness of, for example, between about 20 nm and 500 nm.

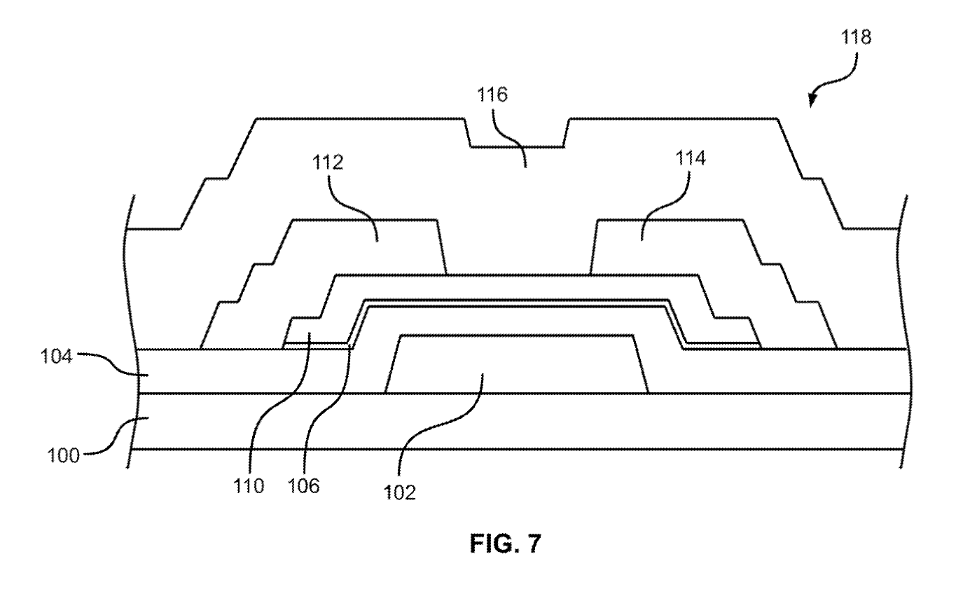

Referring to FIG. 7, a passivation layer 116 is then formed above the source electrode 112, the drain electrode 114, and the exposed portions of the gate dielectric layer 104 and the IGZO channel layer 110. In some embodiments, the passivation layer 116 is made of silicon oxide, silicon nitride, aluminum oxide, aluminum nitride, or a combination thereof and has a thickness of, for example, between about 0.1 micrometers (μm) and about 1.5 μm.

The deposition of the passivation layer 116 may substantially complete the formation of an IGZO device 118, such as an inverted, staggered bottom-gate IGZO TFT. It should be understood that although only a single device 118 is shown as being formed on a particular portion of the substrate 100 in FIGS. 1-7, the manufacturing processes described above may be simultaneously performed on multiple portions of the substrate 100 such that multiple devices 118 are simultaneously formed, as is commonly understood. Further, although not shown, in some embodiments, such as those intended for use in display applications, pixel electrodes may also be formed above the substrate 100 during the formation of the IGZO device(s) 118. The pixel electrodes may be made of a transparent conductive material, such as indium-tin oxide (ITO).

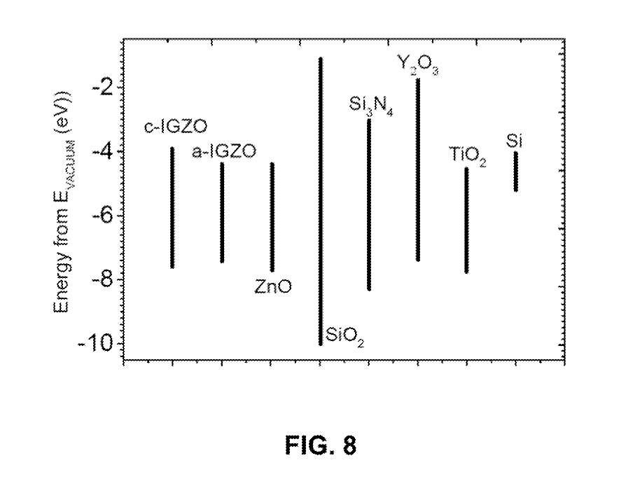

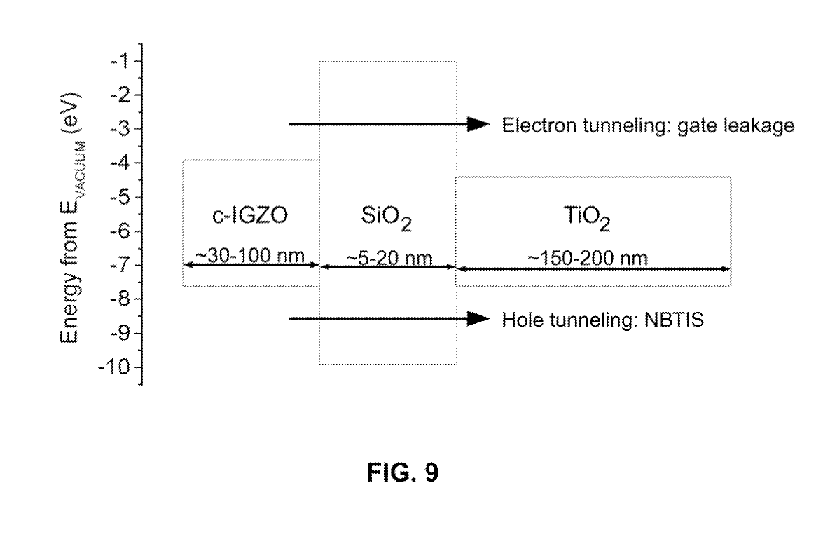

FIGS. 8 and 9 are diagrams comparing the energy bands of various materials, including IGZO, silicon oxide, and titanium oxide. The diagrams shown have been constructed based on data reported for electron affinity and band gaps of different materials. The energy band diagram shown in FIG. 8 depicts band offsets of the valence and conduction bands for different insulator materials (i.e., zinc oxide, silicon oxide, silicon nitride, yttrium oxide, titanium oxide, and silicon) with respect to c-IGZO and a-IGZO. The diagram shown in FIG. 9 depicts only the band offsets for c-IGZO, silicon oxide, and titanium oxide (i.e., the materials described above for use in the channel layer, interface layer, and gate dielectric layer, respectively).

It can be seen in FIG. 8 that titanium oxide alone (i.e., as a high-k gate dielectric material) will achieve high gate capacitance. However, the band offsets with respect to c-IGZO or a-IGZO will result in high electron tunneling current, which increases the off-state leakage of the TFT, and high hole tunneling current, which will result in very high threshold voltage shift during NBIS.

However, if silicon oxide and titanium oxide are used together (as described above), a high gate capacitance, along with an improved (i.e., increased) drive current, may be achieved along with reduced gate leakage current. At the same time, the “hole barrier height” at the interface between the gate dielectric layer and the IGZO may be enhanced. As a result, the tunneling and trapping of holes in the gate dielectric layer is reduced (i.e., compared to conventional IGZO devices without the interface layer). Thus, the threshold voltage shift of the device may be reduced, particularly under negative bias illumination temperature stress (NBITS).

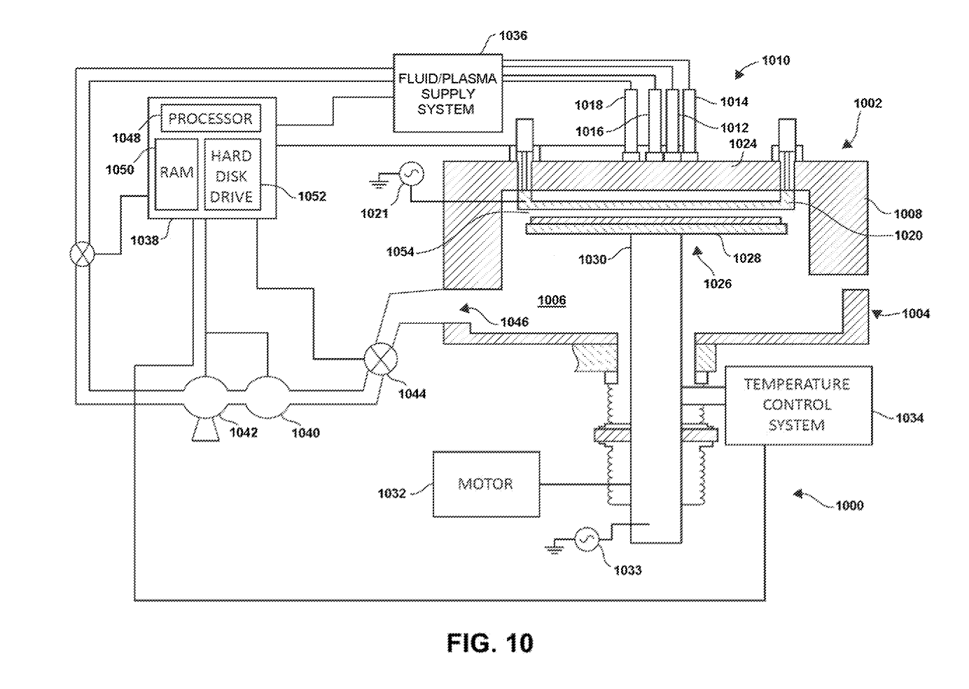

FIG. 10 illustrates a PECVD processing tool (and/or system) 1000 according to some embodiments. The processing tool 1000 may be used to form the interface layer(s) and gate dielectric layer(s) (and/or other components of the IGZO devices) described above.

The processing tool 1000 includes an enclosure assembly 1002 formed from a process-compatible material, such as aluminum or anodized aluminum. The enclosure assembly 1002 includes a housing 1004, which defines a processing chamber 1006, and a vacuum lid assembly 1008 covering an opening to the processing chamber 1006 at an upper end thereof. Although only shown in cross-section, it should be understood that the processing chamber 1006 is enclosed on all sides by the housing 1004 and/or the vacuum lid assembly 1008.

A process fluid injection assembly 1010 is mounted to the vacuum lid assembly 1008 and includes a plurality of passageways (or injection ports) 1012, 1014, 1016, and 1018 and a showerhead 1020 to deliver reactive and carrier fluids into the processing chamber 1006. In the embodiment depicted in FIG. 10, the showerhead 1020 is moveably coupled to an upper portion of the vacuum lid assembly 1008 (i.e., a backing plate 1024). The showerhead 1020 may be formed from any known material suitable for the application, including stainless steel, aluminum, anodized aluminum, nickel, ceramics and the like. As shown, power supply 1021 is coupled to the showerhead 1020.

Referring again to FIG. 10, the processing tool 1000 also includes a heater/lift assembly 1026 disposed within processing chamber 1006. The heater/lift assembly 1026 includes a support pedestal (or substrate support) 1028 connected to an upper portion of a support shaft 1030. The support pedestal 1028 is positioned between shaft 1030 and the backing plate 1024 and may be formed from any process-compatible material, including aluminum nitride and aluminum oxide. The support pedestal 1028 is configured to hold or support a substrate and may be a vacuum chuck, as is commonly understood, or utilize other conventional techniques, such as an electrostatic chuck (ESC) or physical clamping mechanisms, to prevent the substrate from moving on the support pedestal 1028. The support shaft 1030 is moveably coupled to the housing 1004 so as to vary the distance between support pedestal 1028 and the backing plate 1024. That is, the support shaft 1030 may be vertically moved to vary the distance between the support pedestal 1028 and the backing plate 1024. In the depicted embodiment, a lower portion of the support shaft 1030 is coupled to a motor 1032 which is configured to perform this movement. Although not shown, a sensor may provide information concerning the position of the support pedestal 1028 within processing chamber 1006. As shown, power supply 1033 is coupled to the support pedestal 1028 (e.g., through the support shaft 1030).

The support pedestal 1028 may be used to heat the substrate through the use of heating elements (not shown) such as resistive heating elements embedded in the pedestal assembly. In the embodiment shown in FIG. 10, a temperature control system 1034 is provided to control the heating elements, as well as maintain the chamber housing 1004, vacuum lid assembly 1008, and showerhead 1020 within desired temperature ranges in a conventional manner.

Still referring to FIG. 10, the processing tool 1000 also includes a fluid/plasma supply system 1036 and a controller (or system control system) 1038. The fluid/plasma supply system 1036 is in fluid communication with the passageways 1012, 1014, 1016, and 1018 through a sequence of conduits (or fluid lines).

Although not shown in detail, the fluid/plasma supply system 1036 includes one or more supplies of various processing fluids (e.g., precursors, reagents, etc.) and a plasma generator (e.g., a remote plasma generator). The fluid/plasma supply system 1036 (and/or the controller 1038) controls the flow of processing fluids and plasma to, from, and within the processing chamber 1006 with a pressure control system that includes, in the embodiment shown, a turbo pump 1040 and a roughing pump 1042. The turbo pump 1040 and the roughing pump 1042 are in fluid communication with processing chamber 1006 via a butterfly valve 1044 and a pump channel 1046.

The controller 1038 includes a processor 1048 and memory, such as random access memory (RAM) 1050 and a hard disk drive 1052. The controller 1038 is in operable communication with the various other components of the processing tool 1000, including the turbo pump 1040, the temperature control system 1034, the fluid/plasma supply system 1036, and the motor 1032 and controls the operation of the entire processing tool 1000 to perform the methods and processes described herein.

During operation, the processing tool 1000 establishes conditions in a processing region 1054 between an upper surface of the substrate and the showerhead 1020, such as injecting precursors (or reagents), as well as purge gases, to form the desired material on the surface of the substrate. The power supplies 1021 and 1033 may be used to pulse direct current (DC) power and/or alternating current (AC) power to the showerhead 1021 and the support shaft 1033, respectively, to assist in the formation of the desired material on the substrate.

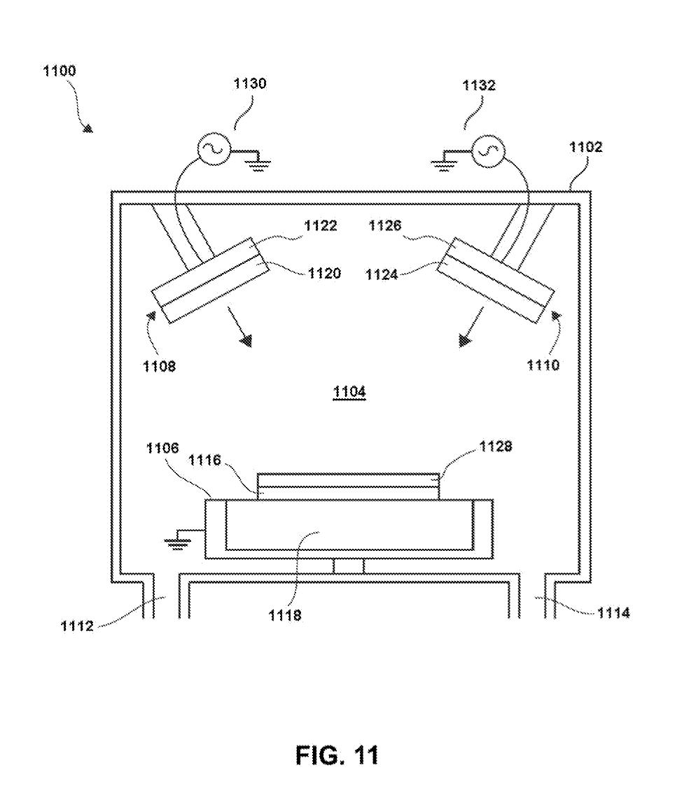

FIG. 11 provides a simplified illustration of a physical vapor deposition (PVD) tool (and/or system) 1100 which may be used, in some embodiments, to form some of the components of the IGZO devices described above. The PVD tool 1100 shown in FIG. 11 includes a housing 1102 that defines, or encloses, a processing chamber 1104, a substrate support 1106, a first target assembly 1108, and a second target assembly 1110.

The housing 1102 includes a gas inlet 1112 and a gas outlet 1114 near a lower region thereof on opposing sides of the substrate support 1106. The substrate support 1106 is positioned near the lower region of the housing 1102 and in configured to support a substrate 1116. The substrate 1116 may be a round substrate having a diameter of, for example, about 200 mm or about 300 mm. In other embodiments (such as in a manufacturing environment), the substrate 1116 may have other shapes, such as square or rectangular, and may be significantly larger (e.g., about 0.5 m to about 4 m across). The substrate support 1106 includes a support electrode 1118 and is held at ground potential during processing, as indicated.

The first and second target assemblies (or process heads) 1108 and 1110 are suspended from an upper region of the housing 1102 within the processing chamber 1104. The first target assembly 1108 includes a first target 1120 and a first target electrode 1122, and the second target assembly 1110 includes a second target 1124 and a second target electrode 1126. As shown, the first target 1120 and the second target 1124 are oriented or directed towards the substrate 1116. As is commonly understood, the first target 1120 and the second target 1124 include one or more materials that are to be used to deposit a layer of material 1128 on the upper surface of the substrate 1116.

The materials used in the targets 1120 and 1124 may, for example, include indium, gallium, zinc, tin, silicon, silver, aluminum, manganese, molybdenum, zirconium, hafnium, titanium, copper, or any combination thereof (i.e., a single target may be made of an alloy of several metals). In some embodiments, the materials used in the targets may include oxygen, nitrogen, or a combination of oxygen and nitrogen in order to form oxides, nitrides, and oxynitrides. Additionally, in some embodiments, the material(s) in the targets are doped (e.g., with sulfur and/or cadmium) as described above (e.g., sulfur-doped zinc oxide, cadmium-doped IGZO, etc.). Further, although only two targets 1120 and 1124 are shown, additional targets may be used.

The PVD tool 1100 also includes a first power supply 1130 coupled to the first target electrode 1122 and a second power supply 1132 coupled to the second target electrode 1124. As is commonly understood, in some embodiments, the power supplies 1130 and 1132 pulse direct current (DC) power to the respective electrodes, causing material to be, at least in some embodiments, simultaneously sputtered (i.e., co-sputtered) from the first and second targets 1120 and 1124. In some embodiments, the power is alternating current (AC) to assist in directing the ejected material towards the substrate 1116.

During sputtering, inert gases (or a plasma species), such as argon or krypton, may be introduced into the processing chamber 1104 through the gas inlet 1112, while a vacuum is applied to the gas outlet 1114. The inert gas(es) may be used to impact the targets 1120 and 1124 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 11, the PVD tool 1100 may also include a control system having, for example, a processor and a memory, which is in operable communication with the other components shown in FIG. 11 and configured to control the operation thereof in order to perform the methods described herein.

Although the PVD tool 1100 shown in FIG. 11 includes a stationary substrate support 1106, it should be understood that in a manufacturing environment, the substrate 1116 may be in motion (e.g., an in-line configuration) during the formation of various layers described herein.

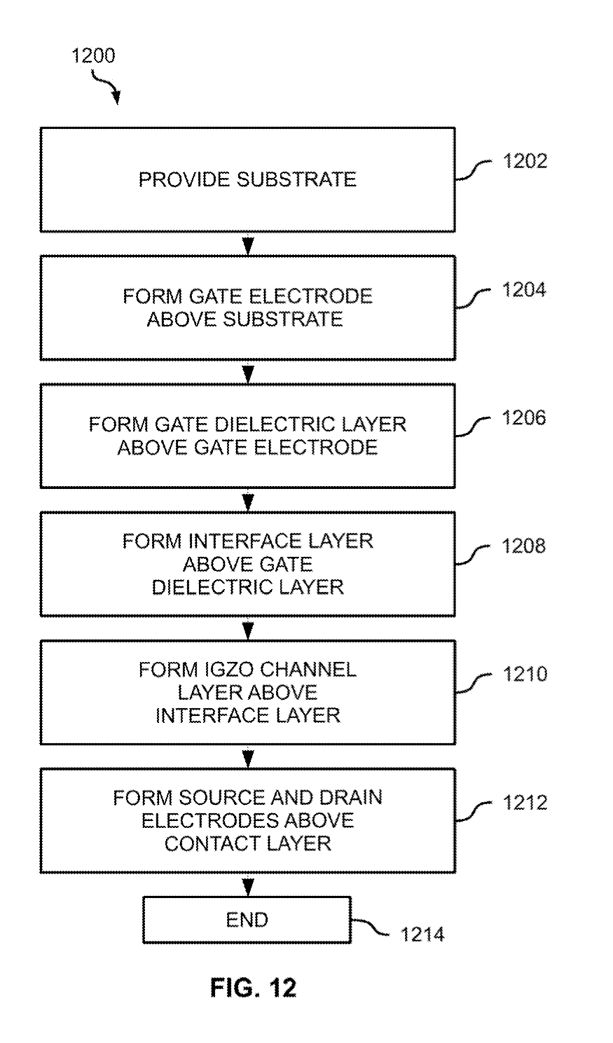

FIG. 12 illustrates a method 1200 for forming IGZO devices, such as IGZO TFTs, according to some embodiments. At block 1202, the method 1200 begins with a substrate being provided. As described above, in some embodiments, the substrate includes glass, a semiconductor material, or a combination thereof.

At block 1204, a gate electrode is formed above the substrate. The gate electrode may be made of a conductive material, such as copper, silver, aluminum, manganese, molybdenum, or a combination thereof.

At block 1206, a gate dielectric layer is formed above the gate electrode. In some embodiments, the gate dielectric layer is made of titanium oxide. The gate dielectric layer may have a thickness of, for example, between about 150 nm and about 200 nm. The gate dielectric layer may be formed using PVD, CVD, PECVD, or ALD.

At block 1208, an interface layer is formed above the gate dielectric layer. In some embodiments, the interface layer is made of silicon oxide. The interface layer may have a thickness of, for example, between about 5 nm and about 20 nm. In some embodiments, the interface layer is formed using PECVD.

At block 1210, an IGZO channel layer is formed above the interface layer. In some embodiments, the IGZO within the IGZO layer is deposited as a-IGZO. However, in some embodiments, the IGZO is formed or deposited using processing conditions to enhance the crystalline structure thereof.

At block 1212, source and drain electrodes are formed above the interface layer. The source and drain electrodes may made of, for example, titanium, aluminum, molybdenum, copper, copper-manganese alloy, or a combination thereof.

Although not shown, in some embodiments, the method 1200 includes the formation of additional components of an IGZO device, such as a passivation layer, as well as additional processing steps, such as an annealing process. At block 1214, the method 1200 ends.

Thus, in some embodiments, methods for forming an IGZO device are provided. A substrate is provided. A gate electrode is formed above the substrate. A gate dielectric layer is formed above the gate electrode. The gate dielectric layer includes titanium. An interface layer is formed above the gate dielectric layer. The interface layer includes silicon. An IGZO channel layer is formed above the interface layer. A source electrode and a drain electrode are formed above the IGZO channel layer.

In some embodiments, methods for forming an IGZO device are provided. A substrate is provided. A gate electrode is formed above the substrate. A gate dielectric layer is formed above the gate electrode. The gate dielectric layer includes titanium oxide. An interface layer is formed above the gate dielectric layer. The interface layer includes silicon oxide. An IGZO channel layer is formed above the interface layer. A source electrode and a drain electrode are formed above the IGZO channel layer. A passivation layer is formed above the source electrode and the drain electrode.

In some embodiments, IGZO devices are provided. Each IGZO device includes a substrate. A gate electrode is formed above the substrate. A gate dielectric layer is formed above the gate electrode. The gate dielectric layer includes titanium oxide. An interface layer is formed above the gate dielectric layer. The interface layer includes silicon oxide. An IGZO channel layer is formed above the interface layer. A source electrode and a drain electrode are formed above the IGZO channel layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming an indium-gallium-zinc oxide (IGZO) device, the method comprising:
providing a substrate;
forming a gate electrode above the substrate;
forming a gate dielectric layer above the gate electrode, wherein the gate dielectric layer comprises titanium;
forming an interface layer above the gate dielectric layer, wherein the interface layer comprises silicon;
forming an IGZO channel layer above the interface layer; and
forming a source electrode and a drain electrode above the IGZO channel layer.

2. The method of claim 1, wherein the interface layer has a thickness of between about 5 nanometers (nm) and about 20 nm.

3. The method of claim 2, wherein the gate dielectric layer has a thickness of between about 150 nm and about 200 nm.

4. The method of claim 1, wherein the gate dielectric layer comprises titanium oxide and the interface layer comprises silicon oxide.

5. The method of claim 4, wherein the interface layer is formed using plasma enhanced chemical vapor deposition (PECVD).

6. The method of claim 5, wherein the gate dielectric layer is formed using physical vapor deposition (PVD), chemical vapor deposition (CVD), PECVD, or atomic layer deposition (ALD).

7. The method of claim 6, wherein the IGZO channel layer has a thickness of between about 30 nm and about 100 nm.

8. The method of claim 7, wherein the IGZO channel layer comprises crystalline IGZO.

9. The method of claim 8, further comprising forming a passivation layer above the source electrode and the drain electrode.

10. The method of claim 9, wherein the substrate comprises glass, a semiconductor material, or a combination thereof.

11. A method for forming an indium-gallium-zinc oxide (IGZO) device, the method comprising:
providing a substrate;
forming a gate electrode above the substrate;
forming a gate dielectric layer above the gate electrode, wherein the gate dielectric layer comprises titanium oxide;
forming an interface layer above the gate dielectric layer, wherein the interface layer comprises silicon oxide;
forming an IGZO channel layer above the interface layer;
forming a source electrode and a drain electrode above the IGZO channel layer; and
forming a passivation layer above the source electrode and the drain electrode.

12. The method of claim 11, wherein the gate dielectric layer has a thickness of between about 150 nanometers (nm) and about 200 nm.

13. The method of claim 12, wherein interface layer has a thickness of between about 5 nm and about 20 nm.

14. The method of claim 13, wherein the gate dielectric layer is formed using physical vapor deposition (PVD), chemical vapor deposition (CVD), plasma enhanced CVD (PECVD), or atomic layer deposition (ALD).

15. The method of claim 14, wherein the interface layer is formed using PECVD.

16. An indium-gallium-zinc oxide (IGZO) device comprising:
a substrate;
a gate electrode formed above the substrate;
a gate dielectric layer formed above the gate electrode, wherein the gate dielectric layer comprises titanium oxide;
an interface layer formed above the gate dielectric layer, wherein the interface layer comprises silicon oxide;
an IGZO channel layer formed above the interface layer; and
a source electrode and a drain electrode formed above the IGZO channel layer.

17. The IGZO device of claim 16, wherein the interface layer has a thickness of between about 5 nanometers (nm) and about 20 nm.

18. The IGZO device of claim 17, wherein the gate dielectric layer has a thickness of between about 150 nm and about 200 nm.

19. The IGZO device of claim 17, wherein the IGZO channel layer has a thickness of between about 30 nm and about 100 nm.

20. The IGZO device of claim 19, further comprising a passivation layer formed above the source electrode and the drain electrode.
